(19) United States
(12) Patent Application Publication
(10) Pub. No.: US 2013/0098599 A1
(43) Pub. Date: Apr. 25, 2013

(54) INDEPENDENT COMPUTER SYSTEM ZONE COOLING RESPONSIVE TO ZONE POWER CONSUMPTION

(71) Applicant: International Business Machines Corporation, Armonk, NY (US)

(72) Inventors: Diane S. Busch, Durham, NC (US); Jason A. Matteson, Raleigh, NC (US)

(73) Assignee: INTERNATIONAL BUSINESS MACHINES CORPORATION, Armonk, NY (US)

(21) Appl. No.: 13/711,671

(22) Filed: Dec. 12, 2012

Related U.S. Application Data
(63) Continuation of application No. 13/276,362, filed on Oct. 19, 2011.

(51) Int. Cl. H05K 7/20

(52) U.S. Cl. CPC H05K 7/20209
USPC 165/294; 165/247

(57) ABSTRACT

Methods are disclosed for independently cooling each of a plurality of zones of a computer system in relation to their respective zone power consumptions. In one example method, a power consumption of heat-generating devices is monitored at each of a plurality of zones of a computer system. A cooling fluid flow rate to each zone is independently controlled. One of the zones is targeted for increased cooling in response to a detected increase in power consumption in the targeted zone. The cooling fluid flow rate to the targeted zone is then increased in immediate response to the power consumption increase.

### CROSS-REFERENCE TO RELATED APPLICATIONS

This application is a continuation of co-pending U.S. patent application Ser. No. 13/276,362, filed on Oct. 19, 2011.

### BACKGROUND

1. Field of the Invention

The present invention relates to power management and cooling in a computer system, such as in a data center.

2. Background of the Related Art

A data center is a facility where computer equipment and related infrastructure are consolidated for centralized operation and management. Computer equipment may be interconnected in a datacenter to produce large, powerful computer systems that are capable of meeting the computing requirements of entities that store and process large amounts of data, such as corporations, web hosting services, and Internet search engines. A data center may house any number of racks, with each rack capable of holding numerous modules of computer equipment. The computer equipment typically includes a large number of rack-mounted servers along with supporting equipment, such as switches, power supplies, network communications interfaces, environmental controls, and security devices. These devices are typically mounted in racks in a compact, high-density configuration to make efficient use of space while providing physical access and enabling the circulation of cool air.

Two important aspects of operating a datacenter are managing power consumed by the equipment and providing adequate cooling. The large amount of rack-mounted computer equipment in a datacenter may collectively consume a large quantity of power and generate a large amount of heat. The infrastructure provided in a datacenter is intended to support these significant power and cooling demands. For example, the datacenter may provide electrical utilities with the capacity to power a large volume of rack-mounted computer equipment, and a cooling system capable of removing the large quantity of heat generated by the rack-mounted computer equipment. The cooling system in many installations will also include a particular arrangement of equipment racks into alternating hot aisles and cold aisles, and a computer room air conditioner (“CRAC”) capable of supplying chilled air to the cold aisles. Meanwhile, chassis-mounted blower modules help move the chilled air through the racks to remove heat from the computer equipment and exhaust the heated air into the hot aisles.

### BRIEF SUMMARY

One embodiment of the present invention provides a method comprising monitoring power consumption of heat-generating devices in each of a plurality of zones of a computer system, independently controlling a cooling fluid flow rate to each zone, and increasing the cooling fluid flow rate to the targeted zone in immediate response to detecting an increase in the power consumption within the targeted zone.

### BRIEF DESCRIPTION OF THE SEVERAL VIEWS OF THE DRAWINGS

FIG. 1 is schematic diagram representing a centrally managed computer system in which each of a plurality of zones is independently cooled in relation to a dynamic zone power consumption.

FIG. 2 is a set of graphs comparing power-dependent zone cooling to temperature-dependent zone cooling in response to increased zone power consumption.

FIG. 3 is a perspective view of the generalized computer system of FIG. 1, more specifically embodied as a data center.

FIG. 4 is a schematic elevation view of an air-cooled equipment rack.

FIG. 5 is a schematic plan view of an alternative rack having a rear-door, air-to-liquid heat exchanger for cooling airflow through the rack.

### DETAILED DESCRIPTION

One embodiment of the invention provides real-time methods for individually cooling a zone of a computer system in response to dynamic zone power consumption. Real-time computing (RTC) is the study of hardware and software systems that are subject to a “real-time constraint,” such as an operational deadline for a system to respond to an event. In the context of a disclosed example embodiment, real-time computing principles are applied to independently identify and respond to the event of a detected power increase in a zone of the computer system, before the detected power increase can cause an appreciable temperature increase in that zone. The real-time response, in this case, targets the zone for increased cooling in response to the detected power increase. The targeted zone is cooled proactively by increasing a cooling fluid flow rate to the targeted zone before a temperature threshold is reached, and preferably before any appreciable temperature increase occurs. The cooling fluid is typically either air being passed through heat-generating components by forced convection, using a fan or blower module, or a chilled liquid (i.e. coolant) pumped through an air-to-liquid heat exchanger. Proactively cooling the targeted zone before the temperature rises reduces the maximum fan speed required to cool the zone. In the case of a fan or blower module, fan power consumption is a cubic function of fan or blower speed. Therefore, minimizing a maximum fan or blower speed reduces cooling costs. Independently cooling each zone of a computer system in this manner also reduces the thermal affects in one zone from being affected by power consumption in a neighboring zone.

Another embodiment of the invention provides a computer system comprising a plurality of heat-generating computer devices arranged in a data center, a cooling system in the data center, and a real-time cooling controller. The cooling system is configured for directing a cooling fluid to a plurality of different zones of the computer system, where each zone is occupied by a different subset of the heat-generating devices. The real-time cooling controller is configured for monitoring a power consumption of the heat-generating devices at each zone, independently controlling a cooling fluid flow rate to each zone, targeting one of the zones for increased cooling in response to a detected increase in the power consumption at the targeted zone, and increasing the cooling fluid flow rate to the targeted zone in immediate response to the power consumption increase.

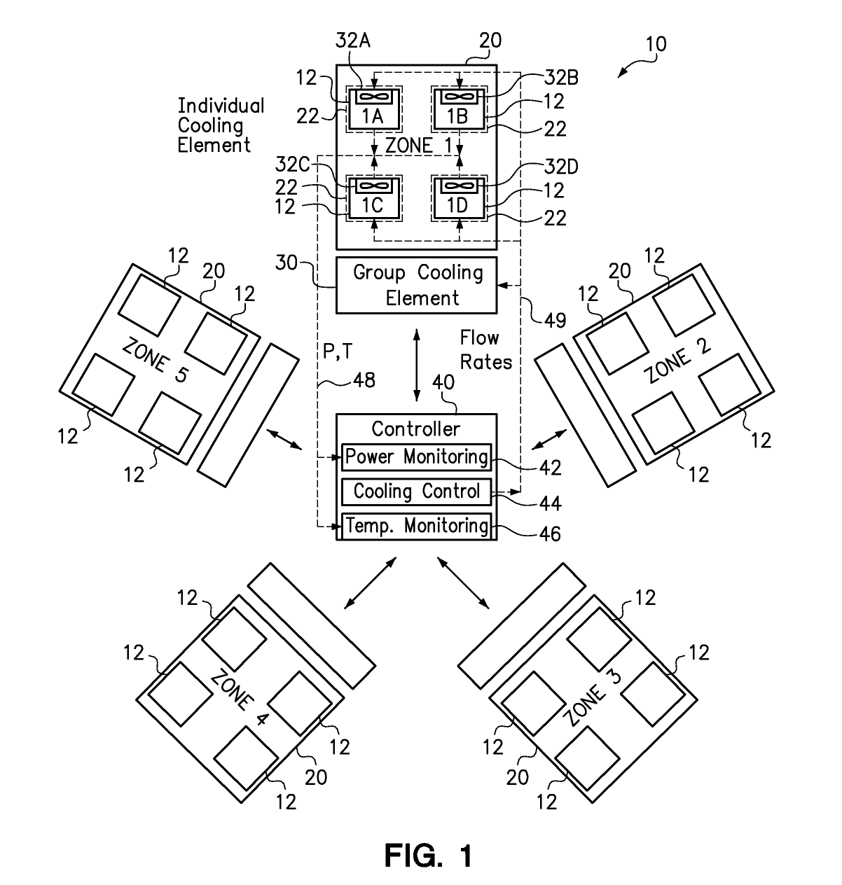

FIG. 1 is a schematic diagram representing a centrally managed computer system 10 in which each of a plurality of zones 20 is independently cooled in relation to a dynamic zone power consumption. The computer system 10 includes a plurality of computer devices 12 that are physically arranged into the different zones 20. In one embodiment described below, for example, each zone 20 includes one or more equipment racks in a data center, and the computer devices 12 include servers and other equipment mounted in the racks. The zones 20 and the arrangement of the computer devices 12 may be selected by a computer system designer depending on such design factors as the amount of space provided, the quantity, type, and positioning of heat-generating computer devices 12, and the type, quantity, and positioning of cooling elements such as fans, blowers, and air-conditioning units. For purpose of illustration, the computer system 10 in FIG. 1 is organized into five zones (zone 1 to zone 5), with four computer devices 12 per zone 20. Each zone 20 is further divided into additional zones 22 within each zone 20. Zones 1 to 5 may alternatively be referred to as “primary zones” and the zones 22 within the primary zones 20 may be alternatively referred to as “sub-zones.” In this example, each primary zone 20 includes four sub-zones 22 (e.g. sub-zones 1A to 1D of zone 1). There is one computer device 12 per sub-zone 22 in this example, although there may be more than one computer device 12 per sub-zone in another embodiment.

Each computer device 12 consumes electrical power and generates heat as a byproduct of, and in proportion to, its power consumption. The power consumption within a particular zone 20, 22 (i.e. “zone power consumption”) includes a net power consumption of the computer devices 12 in that zone 20, 22. For example, the zone power consumption for zone 1 is the net power consumption of the four computer devices 12 in zone 1, and the zone power consumption for each sub-zone 1A to 1D in zone 1 is the power consumption of the corresponding computer device 12. A plurality of cooling elements are provided for cooling the computer system 10 by directing a cooling fluid to the various zones 20 and sub-zones 22. The cooling fluids may be chilled air or chilled liquid. The cooling elements 30, 32 may include fans for directing airflow to the computer devices 12 or liquid-cooled heat exchangers for directing chilled liquid coolant to the computer devices 12. In this case, one cooling element is provided for each zone 20, 22, so that each cooling element controls a cooling fluid flow rate to a particular zone 20, 22. The cooling elements in the computer system 10 include one group cooling element 30 for each primary zone 20 and an optional device cooling element 32 for each computer device 12 for directing a cooling fluid to the sub-zone 22 associated with that computer device 12. While one cooling element is provided for each zone, an alternative system may include a cooling element shared by two or more zones and capable of independently controlling the cooling fluid flow rate to each.

A controller 40 centrally manages the independent cooling of each zone (including the sub-zones 22 within each zone) of the computer system 10. The controller 40 is in communication with components within each zone 20, 22. The controller 40 includes power monitoring control logic 42 for monitoring the zone power consumption of each zone 20, 22, temperature monitoring control logic 46 for monitoring a temperature in each zone 20, 22, and cooling control logic 44 for independently adjusting the cooling fluid flow rate to each zone 20, 22 in relation to its temperature and power consumption. Dynamic power consumption and temperature signals 48 may be generated in each of the zones 20, 22. These power consumption signals may include a group power consumption in each of the primary zones 20 and the power consumptions of individual computer devices 12 in the respective sub-zones 22. For example, in a data center, the power consumption signals may include the power consumptions of individual servers and the power consumptions of a rack or rack-mounted server chassis having a plurality of servers. The controller 40 outputs flow rate control signals 49 to individually adjust the cooling rates in the various zones 20, 22 in response to the zone temperature and power consumption signals 48.

The controller 40 may individually adjust cooling to each zone 20, 22 in relation to the respective zone temperatures according to the temperature monitoring control logic 46. The temperature monitoring control logic 46 may include temperature thresholds selected for each zone 20, 22, with actions associated with each temperature threshold. For example, in response to reaching a first temperature threshold (e.g. a warning temperature “T_{warn},”) in a particular zone 20, 22, the controller 40 may target that zone for increased cooling, and request an increased cooling fluid flow rate to the targeted zone 20, 22 sufficient to reduce the elevated temperature in that zone. Reaching another temperature threshold (e.g. a critical temperature “T_{crit”}) in a particular zone 20, 22 may cause the controller 40 to target the same zone for increased cooling, and request a maximum cooling fluid flow rate and/or a reduced-power mode of the device(s) 12 in the targeted zone. The temperature monitoring control logic 46 thereby increases cooling in response to increased temperature. The temperature monitoring control logic 46 also prevents the computer system 10 from reaching or operating at excessive temperatures, such as to avoid equipment damage.

The controller 40 uses power monitoring control logic 42 in tandem with the temperature monitoring control logic 46 to independently adjust cooling fluid flow rates to the different zones 20, 22. According to the power monitoring control logic 42, the controller 40 monitors the instantaneous zone power consumption for each zone 20, 22 and makes real-time cooling adjustments to the cooling fluid flow rates in response to the zone power consumption levels. While the temperature monitoring control logic 46 is used by the controller 40 to increase the cooling fluid flow rate to a zone in response to an increased temperature, the power monitoring control logic 42 is used by the controller 40 to identify a power consumption increase within a particular zone and to target that zone for increased cooling. The controller 40 requests an increased cooling fluid flow rate to the targeted zone before any significant temperature increase can occur in the targeted zone.

The power monitoring control logic 42 seeks to reduce the power consumption of the group cooling elements such as fans, blower, or air-to-liquid heat exchangers by reducing the peak values for the cooling fluid flow rates. The power monitoring control logic 42 also helps thermally isolate the different zones 20, 22 by reducing the thermal effect of power consumption in one zone on the temperature of another zone. By increasing cooling to the targeted zone before a significant temperature increase can occur, the temperature in the targeted zone is moderated, along with temperatures in neighboring zones. For example, if power consumption of the computer device 12 in sub-zone 1C of zone 1 suddenly increases, the controller 40 will respond according to the power monitoring control logic 42 by increasing the cooling fluid flow rate supplied by the cooling element 32C to sub-zone 1C. The increased cooling fluid flow rate to sub-zone 1C prevents or moderates a temperature increase at sub-zone 1C, which temperature increase could otherwise also increase the temperature of neighboring sub-zones 1A, 1B, and 1D. Likewise, if power consumption of the group of computer devices 12 in zone 1 suddenly increases, the controller 40 will respond according to the power monitoring control logic 42 by increasing the cooling fluid flow rate supplied by the group cooling element 30 to zone 1. The increased cooling fluid flow rate to zone 1 prevents or moderates a temperature increase in zone 1, which temperature increase could otherwise also increase the temperature of neighboring zones zone 2 and zone 5.

In at least some instances, the power-dependent cooling response according to the power monitoring control logic 42 prevents the temperature in the targeted zone from reaching a temperature threshold. The temperature monitoring control logic 46 can provide redundancy and failsafe operation to the power monitoring control logic in the event that a temperature threshold might still occur. For example, if the computer system 10 experiences unusually high power consumption or an anomaly in a particular zone 20, 22 that is not fully compensated for by the power monitoring control logic 42, the occurrence of a temperature threshold may still trigger a cooling response according to the temperature monitoring control logic 46. Even if one of the cooling elements 30, 32 in a particular zone fails, causing a temperature threshold to occur, the controller 40 may still trigger a power reduction or shutdown to device(s) 12 in that zone according to the temperature monitoring control logic 46.

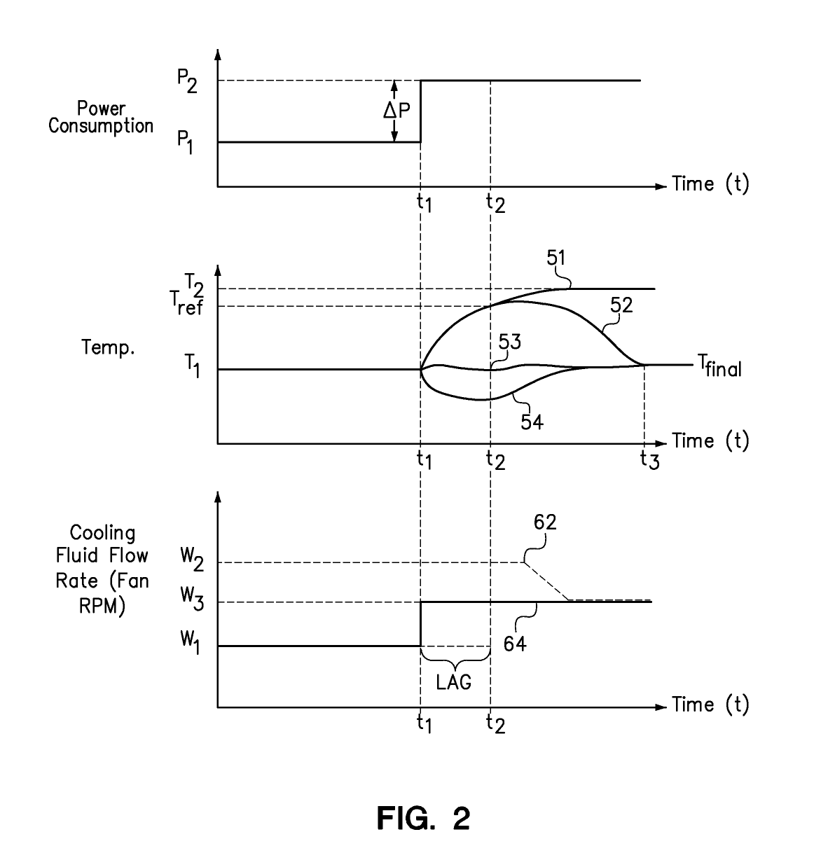

FIG. 2 is a set of three graphs comparing power-dependent zone cooling to temperature-dependent zone cooling in response to a power consumption increase in a zone of the computer system 10 of FIG. 1. In each of the three graphs, the horizontal axis represents time (t). The upper graph has a vertical axis representing power consumption (P), the middle graph has a vertical axis representing temperature (T), and the lower graph has a vertical axis representing cooling fluid flow rate (w), such as a fan RPM.

Prior to time t1, the zone power consumption is at a steady state value of P1, the temperature is at a steady-state value T1, and the cooling fluid flow rate is a steady state w1. In the upper graph, an increase in power from the steady state value of P1 to a new steady-state value P2 is shown to occur at time t1. The amount of the power increase is ΔP. In the middle graph, a first curve 51 plots an expected temperature increase in the absence of any cooling response to the power increase ΔP. Beginning at time t1, the temperature increases slowly with time along upper curve 51 until a new steady-state temperature T2 is reached over time. This case is idealized to assume that the power consumptions P1, P2 are at steady state, and that the zone power consumption remains at each value long enough for the zone to equilibrate to a steady-state temperature value. In an actual system, quasi-steady state values are possible, but a more dynamic power consumption is also possible.

Again in reference to the middle graph, a second curve 52 plots an example of a temperature-dependent cooling response to the power increase ΔP, such as by applying only the temperature monitoring control logic 46 in the computer system 10 of FIG. 1. Accordingly, a predefined temperature threshold Tref has been established, having a value of between T1 and T2. After the power increase from P1 to P2 at time t1, the zone temperature initially increases along upper curve 51 until the temperature reaches the value of Tref. When the temperature reaches Tref, the cooling system responds, according to temperature monitoring control logic, to increase the cooling fluid flow rate to the zone. This increased cooling fluid flow rate is reflected in cure 62 in the lower graph. The increased cooling fluid flow rate removes heat from the zone at an increased rate, which gradually reduces the temperature along curve 52 (or at least prevents the temperature from reaching T2). The amount of the temperature reduction depends on the magnitude of the increased cooling fluid flow rate. In this example, the middle graph shows that the temperature is reduced to a value of greater than T1 but still less than the temperature threshold Tref. Optionally, the increased cooling fluid flow rate may be maintained even as the temperature drops back below Tref. In an alternative implementation, curve 62 shows that the cooling fluid flow rate may be decreased in response to the temperature dropping below Tref. This cycle of increasing the cooling fluid flow rate in response to the temperature reaching Tref and decreasing the cooling fluid flow rate in response to the temperature falling below Tref may establish a cyclical cooling response that maintains the temperature at about Tref.

A third temperature curve 53 plots an example of a power-dependent cooling response to the power consumption increase ΔP, such as by applying only the power monitoring control logic 42 in the computer system 10 of FIG. 1. In the lower graph, curve 64 shows that an increased cooling fluid flow rate w3 is requested in immediate response to the power increase ΔP when it occurs at time t1. The cooling fluid flow rate is thereby increased almost immediately, before any appreciable increase in temperature occurs in the targeted zone, and well before the temperature can reach the temperature threshold Tref. In the third curve 53, the increased cooling fluid flow rate w3 may be matched to the rate of power increase such that the temperature is maintained fairly constant.

Still further, a fourth temperature curve 54 provides another example of a power-dependent cooling response to the power increase ΔP, whereby the targeted zone is cooled to below the present temperature following the detected power increase at time t1. Thus, the temperature is cooled to below T1 before the power increase causes appreciable heating. Ideally, the temperature reduction just offsets the expected amount of heating, so that the temperature returns to the temperature T1.

Focusing on the lower graph, the cooling fluid flow rate, as represented by angular velocity of a fan, is initially at w1. The temperature monitoring control logic 46 and the power monitoring control logic 42 respond differently to the zone power consumption increase ΔP, from P1 to P2, at time t1. The temperature monitoring control logic 46 produces the flow rate or fan speed curve 62, which continues to operate at angular velocity w0 until the temperature reaches a temperature threshold Tref at time t2. According to the temperature monitoring control logic, when the temperature reaches the temperature threshold, an increased cooling fluid flow rate is requested. Since the cooling fluid is air, the cooling fluid flow rate is related to the fan speed. The fan speed is initially increased to a value w2 in response to reaching the temperature threshold. Over time, the increased fan speed cools the devices in the targeted zone, and the fan speed may be reduced to a value w1. By allowing the zone temperature to reach the temperature threshold before increasing the fan speed, the fan speed must be increased to the higher value w2.

The power monitoring control logic 42 produces the flow rate or fan speed curve 64, where the fan speed is immediately increased in response to the power consumption increasing at time t1. Thus, a higher cooling rate is immediately imposed, before any appreciable temperature increase occurs in the zone. Because the zone is cooled proactively, before any appreciable temperature increase, a lower fan speed w3 may be selected and held. The result may be an initial lowering of the zone temperature, as illustrated in the curve 54. As the zone continues to heat at the higher power consumption, the zone temperature eventually increases, but only to about the temperature T1 in the zone prior to the power increase.

Although this is a simplified or idealized case, it illustrates the principle that proactive, power-dependent cooling may result in reducing the maximum fan speed. The power consumption of a fan is proportional to the cube of the fan speed. Thus, even though the temperature-dependent fan speed 62 and the power-dependent fan speed 64 may result in the same final temperature by time t3, the fan will consume more total energy by following the temperature-dependent fan speed curve 62 than by following the power-dependent fan speed curve 64.

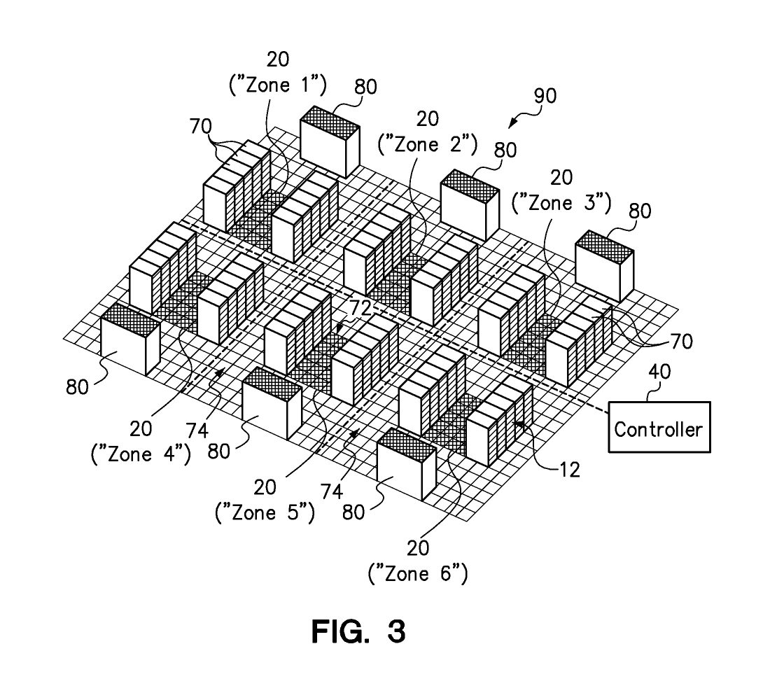

FIG. 3 is a perspective view of a computer system, consistent with the computer system of FIG. 1, embodied as a data center 90. The data center 90 is divided into six zones 20 labeled zone 1 to zone 6. Each zone 20 includes two opposing rows of five computer equipment racks 70. Each rack 70 may have numerous computer devices 12, which will typically include rack-mounted servers and supporting equipment that generate heat in relation to their power consumption. Each zone 20 is provided with a separate computer room air-conditioning (CRAC) unit 80 for cooling the computer devices 12. The racks 70 and computer devices 12 are arranged such that the space between the two rows of racks 70 in each zone 20 is a cold aisle 72, and the spaces on opposing sides of the racks 70 are hot aisles. The layout of the multiple rows of racks 70 in the datacenter 90 therefore produces alternating cold aisles 72 and hot aisles 74. Each CRAC 80 provides chilled air to the cold aisle 72 in the associated zone 20. Through a system of rack-mounted blower modules and/or cooling fans on the computer devices 12, cooled air supplied by the CRAC 80 to the cold aisle 72 is drawn through the devices and exhausted to the hot aisles 74. The heated air exhausted to the hot aisles 74 is recirculated to the CRAC 80, such as through ceiling vents in the hot aisles 74. This creates a cycle of chilled air being supplied to the cold aisles 72 and hot air being returned to the CRAC 80 for repeated cooling.

The central controller 40 is used to monitor the power consumption and temperature in each zone 20 and adjust the airflow in the zone in response to power consumption and temperature measurements, as generally discussed above with reference to the computer system 10 of FIG. 1. In this embodiment of the data center 90, the controller 40 may be provided at an administrator workstation and coupled via one or more network connections to the equipment racks 70 of the respective zones 20 (zone 1 to zone 6). Specifically, the controller 40 may monitor one or more of a device-level power consumption and temperature, a rack level power consumption and temperature, and a zone CRAC level airflow rate and temperature. The power consumption and temperature measurements may be reported individually by the computer devices 12 or collectively from each rack 70, such as by a rack-mounted chassis management module in each rack 70. The power consumption and temperature measurements from each computer device 12 and/or each rack 70 may be combined either at the racks 70, before transmission to the controller 40, or after being separately transmitted to the controller 40. The monitored parameters of the computer devices 12 and the racks 70 in each zone 20, such as power consumption and temperature, may be combined to produce a zone-level power consumption and temperature. As explained above in reference to FIG. 1, the controller 40 may then dynamically adjust the airflow rate within the zone (ie.e the airflow rate of the CRAC units 80) in relation to zone-level power consumption and temperature. The controller 40 may also dynamically adjust the airflow rate provided by the device fans or rack-mounted blower modules in relation to the zone-level power consumption and temperature.

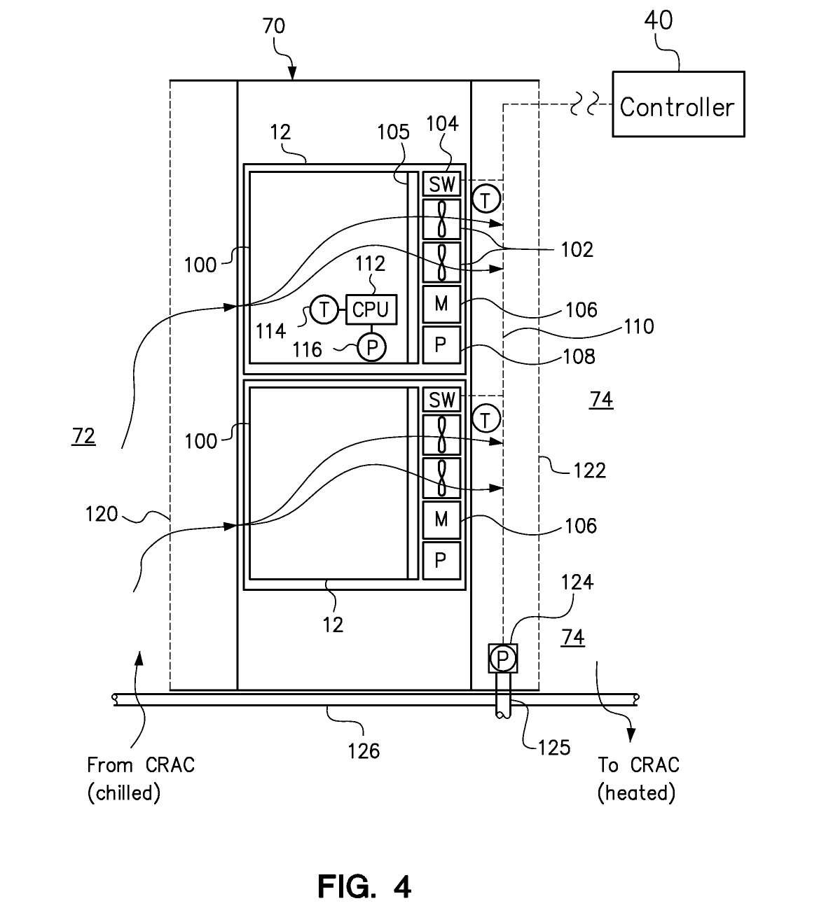

FIG. 4 is a schematic elevation view of an air-cooled equipment rack 70. Two server chassis 100 are mounted in the rack 70. The server chassis 100 each support a plurality of blade servers 12 (only one blade server per chassis is shown), which are treated as individual heat-generating devices that contribute to the net power consumption and heat production of the rack 70. Each server chassis 100 may include a plurality of servers 12, arranged side-by-side (into the page). Each server chassis 100 further includes various support modules, such as redundant blower modules 102, a network switch (“SW”) module 104, and a chassis management (“M”) module 106.

The rack 70 is positioned on a raised data center floor 126. The rack 70 has an air inlet door 120 facing the cold aisle 72 and an air outlet door 122 facing the hot aisle 74. The blower modules 102 draw chilled air from the cold aisle 72 through the server chassis 100 and the individual blade servers 12, and exhaust the heated air to the hot aisle 74. The rack 70 further includes a rack power supply 124 which may be supplied by electrical power cables 125 routed through the raised floor 126. The network switch modules 104 communicate on a communication network 110 that may be shared by all of the racks 70 and the controller 40 in the data center. The power cables 125 supply power to the rack power supply 124, which transforms the supplied power to an appropriate DC power level for output to each of the rack-mounted server chassis 100. The power supplied to each chassis 100 may be connected to a chassis power management (“P”) module 108. The chassis power management module 108 then distributes power to the blade servers 12 through connections on a chassis backplane 105.

The power collecting and reporting system may include one or more power meters for monitoring rack power at different levels within the data center. At the server level, each blade server 12 includes a processor (CPU) section 112, which consumes the most electrical power of any component in the blade server 12. A temperature sensor 114 and power sensor 116 may be in thermal communication with the CPU 112, either of which may be integrated with the CPU 112 (i.e. “on-chip” sensors) or mounted on a motherboard. Each blade server 12 may report its dynamic temperature and power measurements to the chassis management module 106. At the chassis level, the chassis management module may sum the power measurements of the on-board blade servers 12. Alternatively, the management module 106 may simply communicate the individual blade server temperature and power measurements over the network 110 to the controller 40 via the switch module 104. Each chassis 100 may instead measure a chassis power consumption at the power module 108. For example, a power meter integrated with the power module 108 may measure a dynamic power. Any one of the temperatures measured by the individual blade servers 12, such as the maximum temperature measured at one of the blade servers 12 in the chassis 100, may be reported over the network 110 as the chassis temperature. At the rack level, the rack power consumption may be reported as the sum of the chassis power consumption values or as the sum of all the blade server power consumption values. Alternatively, a power meter included with the rack power supply 124 may directly measure the net power consumed at the rack 70A and report the rack power consumption over the network 110. Within a primary zone comprising a plurality of racks 70, as in FIG. 3, a zone power consumption may be computed as the net power consumption of the racks 70 in that zone. Power may also be consumed at the pod level, where a pod is a logical grouping of racks and/or servers based on physical location or interconnectedness.

The temperature and power measurements may be used to control airflow through each rack 70 at the server, chassis, and rack levels in FIG. 4 in the manner generally described above with regard to FIG. 1. For example, the net rack power consumption for the racks 70 in a given zone (see FIG. 3) may be computed as a zone power consumption. The individual racks 70 may then be treated as sub-zones of the primary zone. Likewise, the individual server chassis 100 may be treated as sub-zones of the racks 70, and the individual blade servers 12 in a chassis 100 may be treated as sub-zones of that chassis 100. The power-responsive and temperature-responsive cooling principles generally discussed in FIG. 1 may then be applied to the zone, rack, chassis, and blade server levels. The CRAC units and the blower modules may both be used to control the airflow rate. For example, if the net power consumption in a particular zone increases, the fan speed of the CRAC unit, a temperature of the CRAC unit, and/or the blower speeds of the chassis blower modules 102 may be selectively increased in response to the increase in power consumption. Increasing the airflow rate at the zone level helps to maintain the present zone temperature and to prevent neighboring zones from heating up. At the individual rack level, the blower speeds of one or more chassis blower modules 102 may be selectively increased in response to an increased rack power consumption. Increasing the airflow rate at the rack level helps to maintain the present rack temperatures and to prevent neighboring racks from heating up. At the individual chassis level, increasing the blower speeds in response to an increased chassis power consumption helps to maintain the present chassis temperature and to prevent a neighboring chassis 100 in that rack 70 from heating up. Even at the server level, the speed of an on-board blade server fan (if included) could be increased in response to an increased server power consumption to prevent neighboring blade servers 12 in that same chassis 100 from heating up.

Real-time software uses one or more synchronous programming languages, real-time operating systems, and real-time networks which provide the framework on which to build a real-time software application. A real-time system may be one where its application can be considered (within context) to be mission critical. The anti-lock brakes on a car are a simple example of a real-time computing system—the real-time constraint in this system is the time in which the brakes must be released to prevent the wheel from locking. Real-time computations can be said to have failed if they are not completed before their deadline, where their deadline is relative to an event. A real-time deadline must be met, regardless of system load.

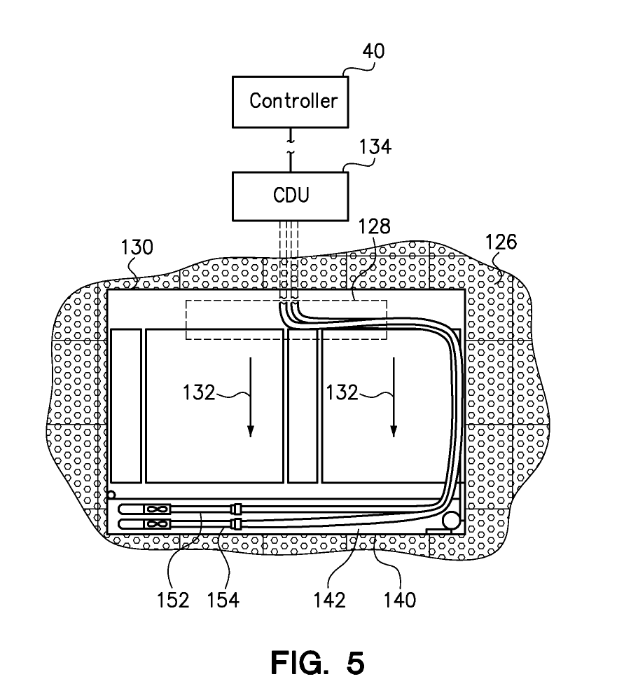

FIG. 5 is a schematic plan view of an alternative, liquid cooled rack 130 having a rear-door, air-to-liquid heat exchanger 140. The rear-door heat exchanger 140 may remove all of the heat that the air took on when passing through the rack 130, such that the use of CRAC units is optional or unnecessary for cooling. The rear-door heat exchanger 140 contains a fin tube assembly 142 with fins that run perpendicular to the plane of the rear-door heat exchanger 140. The rack 130 is positioned on the raised floor 126 of the datacenter, with various power and signal cables routed underneath the raised floor 126 and up through the cable access opening 128 to the rack 130. A supply hose 152 and a return hose 154 are routed from a coolant distribution unit (CDU) 134 to the fin tube assembly 142. The CDU 134 chills recirculated (liquid) coolant to the fin tube assembly 140, preferably in a closed loop. Airflow passes through the rack 130 and through the fin tube assembly 142, which cools the airflow exiting the rack 130. The cooling controller may be in communication with the CDU 134 to proactively increase cooling in response to a power increase in the rack 70B, such as by increasing the flow rate and/or by decreasing the temperature of the coolant supplied by the CDU 134 to the rack 130.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method, comprising:
monitoring power consumption of heat-generating devices in each of a plurality of zones of a computer system;
independently controlling a cooling fluid flow rate to each zone; and
increasing the cooling fluid flow rate to the targeted zone in immediate response to detecting an increase in the power consumption within the targeted zone.

2. The method of claim 1, further comprising:
monitoring the power consumption of the heat-generating devices at each of the plurality of zones of a computer system from a central management location; and
independently selecting the cooling fluid flow rate to each zone from the central management location.

3. The method of claim 1, further comprising:
monitoring a temperature of each zone; and
increasing the cooling fluid flow rate to the targeted zone in immediate response to the power consumption increase by an amount selected to prevent the temperature from increasing above the temperature of the targeted zone at the time of the power consumption increase.

4. The method of claim 1, further comprising:
computing an expected temperature increase in response to the power consumption increase; and
increasing the cooling fluid flow rate to the targeted zone by an amount selected to reduce an actual temperature increase at the targeted zone to less than the expected temperature increase.

5. The method of claim 1, further comprising:
in response to the power consumption increase in the targeted zone, providing a minimum incremental increase in the cooling fluid flow rate to the targeted zone needed to maintain the temperature in the targeted zone below a predefined temperature threshold.

6. The method of claim 1, further comprising:
cooling the computer system with a plurality of cooling elements, each cooling element directing the cooling fluid at a different location of the computer system;
identifying the nearest cooling element to the targeted zone; and
using the nearest cooling element to increase the cooling fluid flow rate to the targeted zone.

7. The method of claim 1, wherein each zone contains one or more equipment racks, and the heat-generating devices include servers mounted in the equipment racks.

8. The method of claim 7, wherein the step of increasing the cooling fluid flow rate to the targeted zone comprises:
increasing the airflow rate of a room-level computer room air conditioning unit providing airflow to the targeted zone.

9. The method of claim 7, wherein the step of increasing the cooling fluid flow rate to the targeted zone comprises:
increasing a fan speed of one or more servers or blower modules in the one or more equipment racks of the targeted zone.

10. The method of claim 7, wherein the step of increasing the cooling fluid flow rate to the targeted zone comprises:
one or both of increasing a flow rate or decreasing a temperature of chilled liquid coolant to the one or more equipment racks in the targeted zone.

11. The method of claim 1, further comprising:
identifying and quantifying an increasing average power consumption over a target time interval; and
wherein the step of increasing the cooling fluid flow rate to the targeted zone in immediate response to the power consumption increase comprises increasing the cooling fluid flow rate to the targeted zone in response to the increasing average power consumption exceeding a predefined power consumption threshold.

12. The method of claim 1, further comprising:
increasing the cooling fluid flow rate to the targeted zone in immediate response to the power consumption increase by an amount sufficient to temporarily reduce the temperature at the target zone prior to a temperature increase at the targeted zone attributable to the power consumption increase.

13. The method of claim 1, further comprising:
increasing the cooling fluid flow rate to the targeted zone by an amount selected as a function of the magnitude of the power consumption increase.

14. The method of claim 1, wherein each zone comprises a different pod.
